(19) United States
(12) Patent Application Publication
(10) Pub. No.: US 2015/0051736 A1
(43) Pub. Date: Feb. 19, 2015

(54) BRACKET AND ROBOT DEMONSTRATOR USING THE SAME

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: SHAO-LONG MU, Shenzhen (CN); CHUN-TIAN FAN, Shenzhen (CN); CHI MING HSU, New Taipei (TW)

(21) Appl. No.: 14/455,343

(22) Filed: Aug. 8, 2014

(30) Foreign Application Priority Data
Aug. 13, 2013 (CN) 2013103506858

(51) Int. Cl. B25J 9/16; G06F 1/16; H01R 13/639; H05K 5/00; H05K 5/02

(52) U.S. Cl. CPC B25J 9/161; H05K 5/0086; H05K 5/0204; H01R 13/639; G06F 1/1683; Y10S 901/46
USPC 700/264; 248/316.5; 439/312; 361/679.58; 901/46

(57) ABSTRACT

A bracket of a robot demonstrator for supporting a tablet computer is disclosed. The bracket includes a bar linkage assembly, a first clamping member pivoted with the bar linkage assembly, and a second clamping member positioned opposite to the first clamping member and pivoted with the bar linkage assembly. A distance between the first clamping member and the second clamping member can be adjusted via adjusting a length of the bar linkage assembly for clamping and supporting the tablet computer.

### FIELD

The subject matter herein generally relates to a bracket, and particularly to a demonstrator bracket and a robot demonstrator using the same.

### BACKGROUND

A robot demonstrator for a robot is positioned adjacent to the robot for programming and inputting control parameters. The demonstrator usually includes a tablet computer and a bracket supporting the tablet computer.

### BRIEF DESCRIPTION OF THE DRAWINGS

Implementations of the present technology will now be described, by way of example only, with reference to the attached figures.

FIG. 1 illustrates an isometric view of a demonstrator including a tablet computer and a bracket.

FIG. 2 illustrates an isometric view of the bracket of FIG. 1.

FIG. 3 is similar to FIG. 2, but viewed from another angle.

FIG. 4 illustrates an exploded view of the bracket of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

A bracket can be used in a robot demonstrator for supporting a tablet computer is disclosed. The bracket includes a bar linkage assembly, a first clamping member, and a second clamping member. The first clamping member and the second clamping member are oppositely pivoted with the bar linkage assembly. A distance between the first clamping member and the second clamping member can be adjusted via adjusting a length of the bar linkage assembly for clamping and supporting the tablet computer.

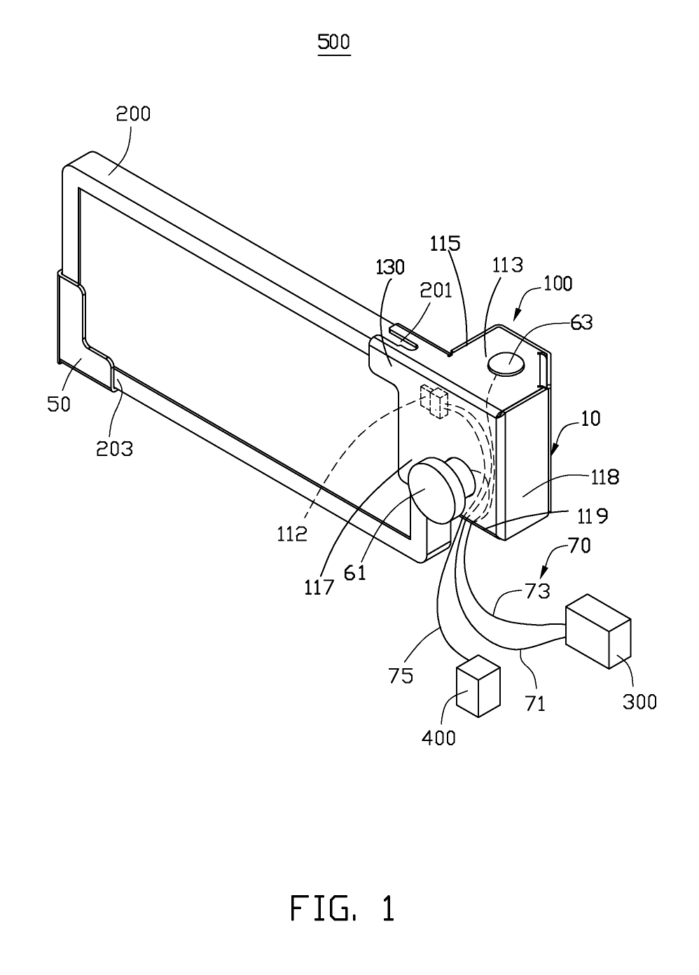

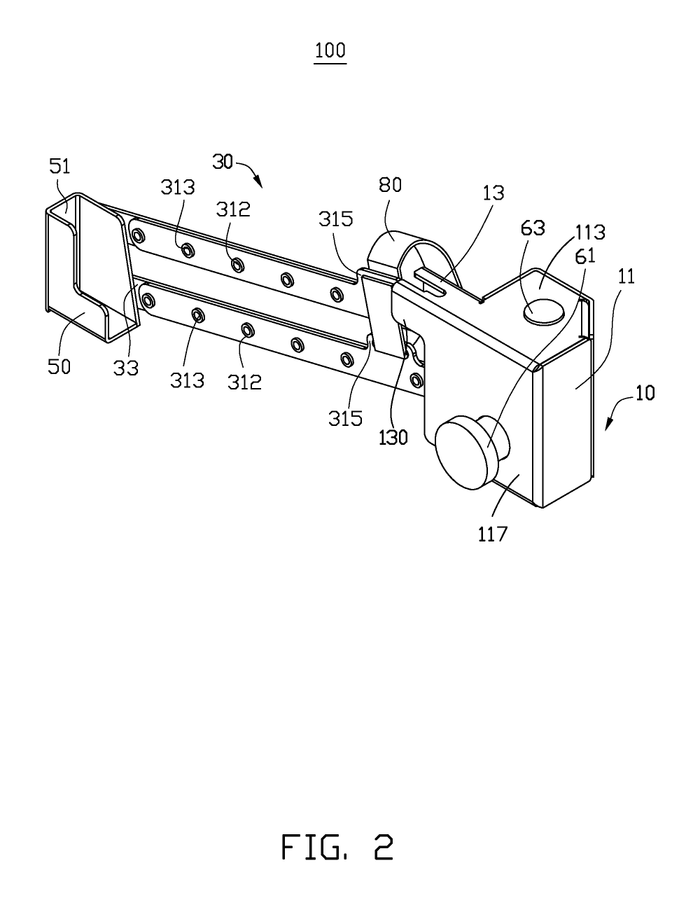

FIG. 1 illustrates a robot demonstrator 500 including a bracket 100 and a tablet computer 200 supported by the bracket 100. The tablet computer 200 is used for programming and inputting control parameters. The tablet computer 200 can control a robot (not shown). In an illustrated embodiment, the tablet computer 200 can include a first corner portion 201 and a second corner portion 203. The first corner portion 201 and the second corner portion 203 can be positioned at a diagonal line of the tablet computer 200. FIG. 2 shows the bracket 100 can include a first clamping member 10, a bar linkage assembly 30, a second clamping member 50, a stop button 61, a manual button 63, and a cable 70 (as shown in FIG. 1). The first clamping member 10 and the second clamping member 50 can be oppositely pivoted with the bar linkage assembly 30. The stop button 61 and the manual button 63 can be positioned on the second clamping member 50.

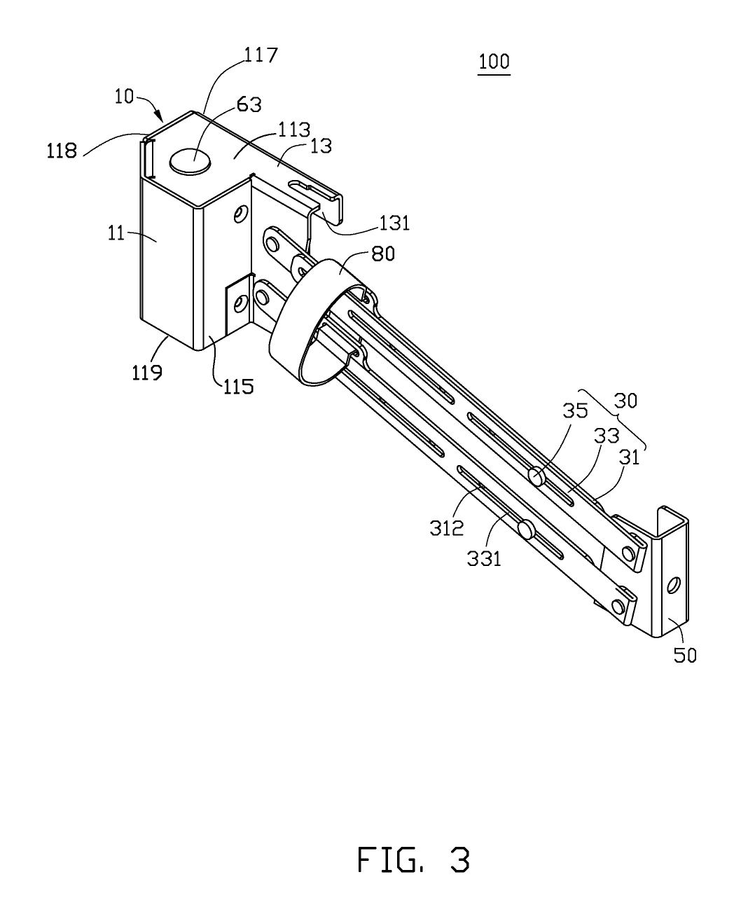

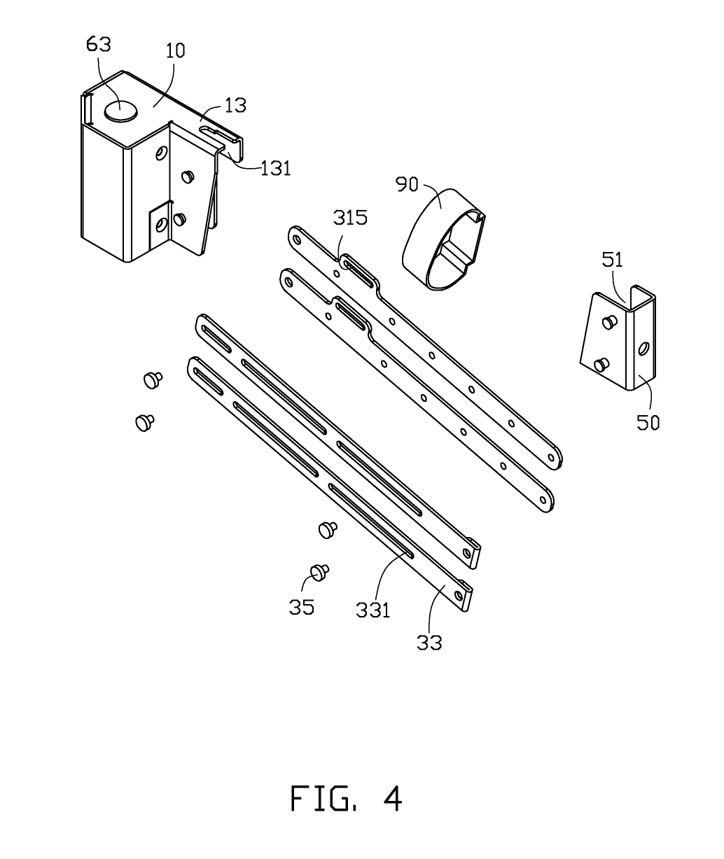

FIG. 3 illustrates the first clamping member 10 can include a mounting portion 11 and a clamping portion 13. The mounting portion 11 can be substantially a hollow cubic. The mounting portion 11 can include an installation surface 113, a first mounting wall 115, a second mounting wall 117, a third mounting wall 118, and a fourth mounting wall 119. The first mounting wall 115, the second mounting wall 117, the third mounting wall 118, and the fourth mounting wall 119 can extend from edges of the installation surface 113. The first mounting wall 115 and the third mounting wall 118 can be substantially parallel to each other. The first mounting wall 115 can be coupled to the fourth mounting wall 119, and the third mounting wall 118 can be couple to the second mounting wall 117. A connecting head 112 (as shown in FIG. 1) can protrude from the second mounting wall 117. The clamping portion 13 can include two supporting slices 130. FIG. 4 shows the two supporting slices 130 can extend from two the second mounting wall 117 toward a same direction, respectively. The two supporting slices 130 can corporative form a first positioning groove 131 for receiving the first corner portion 201. The connecting head 112 can protrude from an inner side surface of the first positioning groove 131. The first corner portion 201 can be clamped into the first positioning groove 131 and electrically coupled to the connecting head 112.

The bar linkage assembly 30 can include a pair of first connecting rods 31, a pair of second connecting rods 33, and four adjusting members 35. The pair of first connecting rods 31 can be pivoted with one supporting slice 130 and can be substantially parallel to each other. A plurality of first adjustable holes 312 can be defined in each first connecting rod 31 and can be arranged in line along an extension of each of the first connecting rods 31. A fixing portion 313 can protrude from the first connecting rod 31 around an edge of each adjustable hole 312 away from the second connecting rod 33. Each first connecting rod 31 can further include a penetrating portion 315 positioned adjacent to the first clamping member 10. One second connecting rod 33 can be mounted with the corresponding first connecting rod 31. Three striped shaped second adjustable holes 331 are defined in each second connecting rod 33 and can be arranged in line corresponding to the plurality of first adjustable holes 312. Each adjusting member 35 can pass through one second adjustable hole 331 and one corresponding first adjustable hole 312 and can be screwed with the fixing portion 313, such that each second connecting rod 33 can be fixedly mounted on corresponding one first connecting rod 31.

The second clamping member 50 can be pivoted with the two second connecting rods 33 away from the first clamping member 10. The second clamping member 50 can define a second positioning groove 203 for receiving the second corner portion 203. The first corner portion 203 can be clamped into the second positioning groove 51. In the illustrated embodiment, a rubber pad can be positioned on inner walls of the first positioning groove 131 and the second positioning groove 51 for protecting the electronic device 200.

A stop button 61 can be mounted on the installation surface 113. A manual button 63 can be mounted on the second mounting wall 117. When an operator (not shown) holds the mounting portion 11 with his or her hand, a thumb (not shown) press the manual button 63, other fingers will put on the stop button 61. A server 300 of the robot will send a signal to the tablet computer 200 for adjusting positions of shafts of the robot when the operator presses the manual button 63, then the tablet computer 200 receives the signal and automatically opens an operation soft for the robot. The robot can be stopped in emergency when the stop button 61 is pressed.

The cable 70 can include an internet communication wire 71, a charging wire 73, and a transmitting wire 75. The internet communication wire 71 can be coupled between the connecting head 112 and the server 300 for transmitting signal between the tablet computer 200 and the server 300. In the illustrated embodiment, the internet communication wire 71 is used when a wireless internet is poor. The charging wire 73 can be coupled with the tablet computer 200 and an outer power source 400 for charging. The transmitting wire 75 can be electrically coupled with the stop button 61 and the manual button 63.

The bracket 100 can further include a wrist band 80. The wrist band 80 can pass through the two penetrating portions 315 and positioned adjacent to the mounting portion 11. The demonstrator 500 will be removed from the operator and positioned adjacent to the robot for sending the control signal to the server 300 after inputting control parameters or programming.

A length of the bar linkage assembly 30 is adjusted by the four adjusting members 35 corresponding to a size of the tablet computer 200, and then the tablet computer 200 is clamped by the first clamping member 10 and the second clamping member 50. The tablet computer 200 is hold by the bracket 100. The wrist band 80 is sleeved on a wrist of the operator. The operator inputs control parameters or programs with the tablet computer 200. The tablet computer 200 is positioned adjacent to the server 300 for controlling the robot by the wireless internet. And the internet communication wire 71 can be used when the wireless internet is poor.

In other embodiments, the number of the adjusting members 35 is not limited to four; it can be one, two, or others. The number of the first connecting rod 31 is not limited to two, it can be one, three, or more. The number of the second connecting rod 33 corresponds to the first connecting rod 31. The numbers of the first adjustable holes 312, the second adjustable holes 331 are positioned as real apply. The first adjustable hole 312 and the second adjustable hole 331 can be just one, when one of them is strip-shaped holes. The cable 70 and the fixing portions 313 can be omitted. The adjusting members 35 pass through the second adjusting hole 331 and screwed with the first adjustable hole 312.

The embodiments shown and described above are only examples. Many details are often found in the art such as the other features of a first clamping member. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A bracket for supporting a tablet computer used in a robot demonstrator, the bracket comprising:
a bar linkage assembly;
a first clamping member pivotably coupled to the bar linkage assembly; and
a second clamping member positioned opposite to the first clamping member and pivotably coupled to the bar linkage assembly, wherein a distance between the first clamping member and the second clamping member can be adjusted via adjusting a length of the bar linkage assembly for clamping and supporting the tablet computer.

2. The bracket of claim 1, wherein the bar linkage assembly comprises a first connecting rod, a second connecting rod, and a adjusting member, the first connecting rod defines a first adjustable hole and is pivotably coupled to the first clamping member, the second connecting rod defines a second adjustable hole, the second connecting rod is pivotably coupled to the second clamping member, the adjusting member passes through the second adjustable hole and the first adjustable hole and fixed with the first connecting rod for adjusting the length of the bar linkage assembly.

3. The bracket of claim 2, wherein the first clamping member comprises a mounting portion and a clamping portion coupled to the mounting portion, the clamping portion comprises two separate supporting slices protruding from the mounting portion, the two supporting slices cooperative form a first positioning groove for receiving a first corner portion of the tablet computer, and the second clamping member defines a second positioning groove for receiving a second portion of the tablet computer.

4. The bracket of claim 2, wherein a fixing portion protrudes from the first connecting rod around an edge of each first adjustable hole, the adjusting member passes through the second adjustable hole and the first adjustable hole and fixed with the fixing portion.

5. The bracket of claim 3, further comprising an internet communication wire, a connecting head protrudes from an inner side surface of the first positioning groove, and the connecting head is configured for electrically coupling to the tablet computer and the internet communication wire.

6. The bracket of claim 5, where the bracket further comprises a stop button, a manual button, and a transmitting wire, the stop button and a manual button are mounted on the mounting portion, the transmitting wire is electrically coupled between the stop button and a manual button.

7. The bracket of claim 1, wherein the bracket further comprises a charging wire for electrically coupling with the tablet computer and an outer power source for charging.

8. The bracket of claim 1, wherein the first connecting rod further comprises a penetrating portion positioned adjacent to the first clamping member, the bracket further comprises a wrist band, and the wrist band passes through the penetrating portion.

9. A robot demonstrator, comprising:
a tablet computer;
a bracket supporting the tablet computer, the bracket comprising:
a bar linkage assembly;
a first clamping member pivoted with the bar linkage assembly; and
a second clamping member positioned opposite to the first clamping member and pivotably coupled to the bar linkage assembly, wherein a distance between the first clamping member and the second clamping member can be adjusted via adjusting a length of the bar linkage assembly for clamping and supporting the tablet computer.

10. The robot demonstrator of claim 9, wherein the bar linkage assembly comprises a first connecting rod, a second connecting rod, and a adjusting member, the first connecting rod defines a first adjustable hole and is pivotably coupled to the first clamping member, the second connecting rod defines a second adjustable hole, the second connecting rod is pivotably coupled to the second clamping member, the adjusting member passes through the second adjustable hole and the first adjustable hole and fixed with the first connecting rod for adjusting the length of the bar linkage assembly.

11. The robot demonstrator of claim 10, wherein the first clamping member comprises a mounting portion and a clamping portion coupled to the mounting portion, the clamping portion comprises two separately supporting slices protruding from the mounting portion, the two supporting slices cooperative form a first positioning groove for receiving a first corner portion of the tablet computer, and the second clamping member defines a second positioning groove for receiving a second portion of the tablet computer.

12. The robot demonstrator of claim 9, wherein a fixing portion protrudes from the first connecting rod around an edge of each adjustable hole, the adjusting member passes through the second adjustable hole and the first adjustable hole and fixed with the fixing portion.

13. The robot demonstrator of claim 9, wherein the bracket further comprises an internet communication wire, a connecting head protrudes from an inner side surface of the first positioning groove, the connecting head is configured for electrically coupling to the tablet computer and the internet communication wire.

14. The robot demonstrator of claim 13, where the bracket further comprises a stop button, a manual button, and a transmitting wire, the stop button and a manual button are mounted on the mounting portion, the cable further comprises a transmitting wire, the transmitting wire is electrically coupled between the stop button and a manual button.

15. The robot demonstrator of claim 9, wherein the bracket further comprises a charging wire for electrically coupling with the tablet computer and an outer power source for charging.

16. The robot demonstrator of claim 9, wherein the first connecting rod further comprises a penetrating portion positioned adjacent to the first clamping member, the bracket further comprises a wrist band, and the wrist band passes through the penetrating portion.
